(19) United States
(12) Patent Application Publication
(10) Pub. No.: US 2004/0033702 A1
(43) Pub. Date: Feb. 19, 2004

(54) Deposition of thin films by laser ablation

(76) Inventors: Astghik Tamanyan, Oakleigh East (AU); Grigori Tamanyan, Oakleigh East (AU)

Correspondence Address: BAKER & BOTTS, 30 ROCKEFELLER PLAZA, NEW YORK, NY, 10112

(21) Appl. No.: 10/380,843

(22) PCT Filed: Sep. 20, 2001
(86) PCT No.: PCT/AU01/01179

(30) Foreign Application Priority Data
Sep. 20, 2000 (AU) PR 0261

(51) Int. Cl. H01L 21/26; H05B 6/00

(52) U.S. Cl. 438/789; 438/795

(57) ABSTRACT

A method of depositing a thin film on a substrate (2), including ablating a target (16) with a laser beam (12) to create a plume (19) of evaporants extending in a propagation direction away from the target surface (17). The laser beam is focussed a finite distance (d) before the target surface (17) and within the plume (19), thereby imparting increased energy to the evaporants within the plume (19). The target can also be rotated a hihg speed in order to impart a predetermined component of velocity to the evaporants which causes the slower moving evaporants to deflect from the propagation direction and are prevented from being deposited on the substrate. The method is useful in the formation of diamond film and has application in the fields of microchip manufacture, visual display units, solar energy conversion, optics, photonics, protective surfaces, medical uses, and cutting and drilling applications.

### FIELD OF THE INVENTION

The present invention relates to a method of forming a thin film on a substrate by laser ablation of a target, e.g. the technique known as Pulsed Laser Deposition (“PLD”). The invention is particularly suited to the formation of a diamond film but is not so limited and has applications in the formation of films of any material and may be used, for example, in superconductor film growth processes, photonics and semiconductor electronics.

### BACKGROUND OF THE INVENTION

Various techniques of employing PLD in the production of high quality thin films have been investigated for several years.

PLD involves directing a pulsed laser onto a target material placed in a chamber, typically a vacuum chamber. The energy of the laser causes the ablation and evaporation of material from the surface of the target into a plume. The plume consists of a mixture of atoms, ions, molecules and particles or clusters. As material is ablated, the plume expands into the chamber. The energy of evaporants within the plume typically range from a few eV to the order of hundreds of eV. By placing a substrate in the direction of propagation of the plume, the ablated material is deposited in layers on the substrate and a thin film is formed.

The attractiveness of PLD for the production of thin films is well documented, however the process has associated drawbacks that can prevent the formation of high quality thin films. The presence of particulates within the plume degrades the quality of the resultant thin film. Various methods of reducing particulates within the plume and of reducing particulates being deposited on the substrate have been developed.

International patent publication WO99/13127 describes a method of evaporation of a target in a vacuum chamber by laser pulses, the laser being focussed to an optimum intensity in order to eliminate particulates from the plume. The optimal intensity is defined in terms of laser pulse duration and the characteristics of the target material. The laser pulse repetition rate is predetermined so as to produce a continuous flow of evaporated material at the substrate. The pulse repetition rate is typically in the range of kilohertz to hundreds of megahertz; and pulse duration is preferably picosecond or femtosecond. The formation of a thin film by evaporation of a graphite target is described. The thin film was a mixture of sp³ and sp² bonded amorphous carbon. The film was deposited on a silicon substrate with a deposition rate of 5 Å/s, and was nearly free of particulates.

A paper concerning PLD by the inventors of WO99/13127, Rode et al, appears at Journal of Applied Physics 85, No. 8 (Apr. 15, 1999) at page 4222.

International patent publication WO00/22184 describes a method of PLD of thin films, particularly diamond-like carbon films, using a short pulse laser (100 picoseconds or less). The use of such a laser is said to generate a plume composed of single atom ions with no clusters. The use of a high average power femtosecond laser results in deposition rates of up to 25 μm/hr.

U.S. Pat. No. 5,858,478 describes a method of PLD of thin films in which a pulsed laser is used to ablate material from a target surface. A shield is placed in the direct line of sight of the target and the substrate and a magnetic field is used to curve the ions within the plume of ablated material towards the substrate, while neutral particles continue to pass by the substrate. This method avoids large neutral particles being deposited on the substrate.

U.S. Pat. No. 5,411,772 describes a method of laser ablation of a target for the formation of a thin film. The substrate is positioned generally parallel to the propagation direction of the plume of ablated material. The deposition chamber includes a low background pressure of inert or reactive gas to facilitate lateral diffusion (relative to the propagation direction) of the plume. Large, heavy particles do not have significant lateral diffusion and are unlikely to be deposited on the substrate.

It is therefore an object of the invention to provide an improved method of producing a high quality thin film, by selection of desired evaporant energies. The thin films produced are preferably substantially free of particulates.

### SUMMARY OF THE INVENTION

In a first aspect, the invention provides a method of depositing a thin film on a substrate, the method including:

laser ablating a target surface to create a plume of evaporants extending in a propagation direction away from the target surface; and

positioning the substrate in the propagation direction of the plume such that evaporants within the plume are deposited on the substrate;

wherein a laser beam is focussed a finite distance before the target surface so as to position the minimum cross-section of the beam resulting from said focussing within the plume, thereby imparting increased energy to the evaporants within the plume.

Advantageously, the laser ablation is effected by the laser beam. In an alternative embodiment, the laser beam is a second laser beam and said laser ablation is effected by a first laser beam.

The present invention is in part based on the observation that evaporants having a wide range of energies are not always suitable for thin film deposition. It is known that for the purpose of obtaining the desired kinds of bonds in the deposited film, it is necessary to deposit on the substrate only evaporants within the relevant energy range. For example for sp³ bonds in carbon films, the relevant energy range of the evaporants is of the order of 100 eV to 200 eV. Particles or evaporants with lower energies will produce mainly sp² bonds with some sp³ bonds. Particles or evaporants with higher energies on the other hand may destroy existing bonds in the film and produce mixture of sp³ and sp² bonds. The ranges of kinetic energies of evaporants depends on the laser flux on the target, the laser wavelength, and the target material. In order to obtain evaporants with an energy range of 50 eV to 100 eV in the case of a graphite target, and 510 nm wavelength laser, the preferred laser flux on the target surface is in the range of 5×10⁸-10⁹ W/cm² However, adjustment of these parameters alone does not necessarily produce the desired range of energies of particles.

This invention also arose from the knowledge that during the interaction of laser radiation with a target, it is possible to obtain a region of evaporants within the plume that is sufficient to permit effective absorption of the laser energy within the plume. The density of evaporants in that region is called the critical density. This critical density n, depends on the laser wavelength λ (μm) and can be quantified by the formula n=1.1×10²¹/λ². The energy absorption by the evaporants only becomes significant when the laser flux is near 10¹⁰W/cm², or more. The input of laser energy in the region of critical density will produce a “shock wave” that expands in the solid angle of 4π. To obtain the most efficient input of laser energy at that point, the laser pulse duration must be greater than the time for electron thermal conductivity (about 1 ns).

A shock wave is produced in the plume when the density of evaporants within the plume reaches a critical density (as herein defined) at a predetermined distance (in cm):

d=1.38×10⁶(ε/A)^{1/2}Δt

where: ε is the particle of energy in eV

A is the atomic weight of particle

Δt is the rising time of laser pulse (s)

before the target surface, advantageously at the time when the laser flux reaches a maximum during the pulse duration, and with the laser beam preferably focussed within the region of critical density, such that collisional absorption takes place.

The plume of evaporants advantageously includes a region of critical density (as herein defined) and the laser beam is preferably focussed within the region of critical density, such that a shockwave is produced in the plume. The critical density depends on the wavelength of the laser and is preferably above 4×10²¹ evaporants/cm³. Evaporants within the plume that have propagated beyond the region of critical density in a predetermined time are accelerated by the shockwave towards the substrate while evaporants within the plume that have not propagated beyond the region of critical density in the predetermined time are accelerated by the shockwave towards the target surface. The energy needed for the formation of thin films varies according to the target material and the film to be formed.

To this end the present invention provides a process of forming thin films on a substrate by laser ablation of a target to form a deposition plume wherein the laser beam flux in the region of highest density in the plume is adjusted to obtain effective energy absorption by the evaporants so that evaporants attain sufficient energy to deposit on the substrate. The substrate is positioned so that evaporants having energy levels outside a predetermined range to do not deposit on the substrate.

The minimum cross-section of the beam preferably includes substantially the whole of the focal region of the beam. The beam is focussed by a lens and the focal region of the beam is defined as the region of the laser beam immediately before and after the optical focal point of the lens. The mid-point of the focal region is displaced in front of the target surface. The distance depends on the target material and the laser flux but is generally in the range of 1 μm to 10 mm.

Preferably, the cross-section of the laser beam on the target is greater than the minimum cross-section of the laser beam. The use of a shorter focal length lens enables a more powerful flux to be achieved in the focal region and thus increases the energy absorbed in the densest region of the plume. Preferably the focal length is less than 35 cm.

It will be appreciated that the ablated evaporants have a range of velocities within the plume. In a preferred embodiment, a predetermined component of velocity is imparted to the evaporants such that slower moving evaporants within the plume are caused, by the predetermined component of velocity, to deflect from the propagation direction and are prevented from being deposited on the substrate. This velocity depends on the target material but is generally above 2000 rev/min, and more preferably greater than 5000 rev/min, and may be up to 40,000 rev/min.

Preferably, the predetermined component of velocity is imparted by movement of the target, e.g. high speed rotation of a cylindrical target. More preferably, the predetermined component of velocity is substantially tangential to the target surface.

In a second aspect, the invention provides a method of depositing a thin film on a substrate, the method including:

laser ablating a target to create a plume of evaporants, having a range of velocities within the plume, extending in a propagation direction away from the target surface;

focussing a laser beam at a finite distance before the target surface so as to position the minimum cross-section of-the beam resulting from said focussing within the plume, thereby imparting increased energy to the evaporants within the plume;

positioning the substrate in the propagation direction of the plume; and

imparting a predetermined component of velocity to the evaporants;

wherein the substrate is positioned at a predetermined distance from the target surface such that the slower moving evaporants within the plume are caused, by the predetermined component of velocity, to deflect from the propagation direction and are prevented from being deposited on the substrate.

Advantageously, the laser ablation is effected by the laser beam. In an alternative embodiment, the laser beam is a second laser beam and said laser ablation is effected by a first laser beam.

Typical film thicknesses produced using the methods of the invention range from atomic level thickness (ultrathin films) up to films the thickness of which is limited by the rate of deposition and the deposition time.

In a third aspect, the invention provides a method of depositing a thin film on a substrate, the method including:

laser ablating a target to create a plume of evaporants, having a range of velocities within the plume, extending in a propagation direction away from the target surface;

positioning the substrate in the propagation direction of the plume; and

imparting a predetermined component of velocity to the evaporants;

wherein the substrate is positioned at a predetermined distance from the target surface such that the slower moving evaporants within the plume are caused, by the predetermined component of velocity, to deflect from the propagation direction and are prevented from being deposited on the substrate.

In a further aspect, the invention provides a substrate having a thin film deposited on it, the thin film having been deposited on the substrate in accordance with a method aspect of the invention. Preferably, in this aspect of the invention, the substrate is coated with a diamond film.

In a yet further aspect, the invention provides a thin film for deposition on a substrate in accordance with one of the method aspects of the invention. Preferably, the film is a diamond film.

The invention also provides apparatus (as defined in the accompanying claims) for performing the method of each aspect of the invention.

### BRI F DESCRIPTION OF THE DRAWINGS

The invention will now be described by way of example only with reference to the accompanying drawings in which:

FIG. 1 is a diagrammatic view of the PLD arrangement according to an embodiment of the invention;

FIG. 2 is an enlarged diagrammatic view of the focal region and laser plume of FIG. 1;

FIG. 3 illustrates the velocity filtering of evaporants ablated from the target surface using a rotating target surface; and

FIG. 4 is a Raman spectrum of a thin film obtained using the method of an embodiment of the invention.

### DESCRIPTION OF PREFERRED EMBODIMENTS

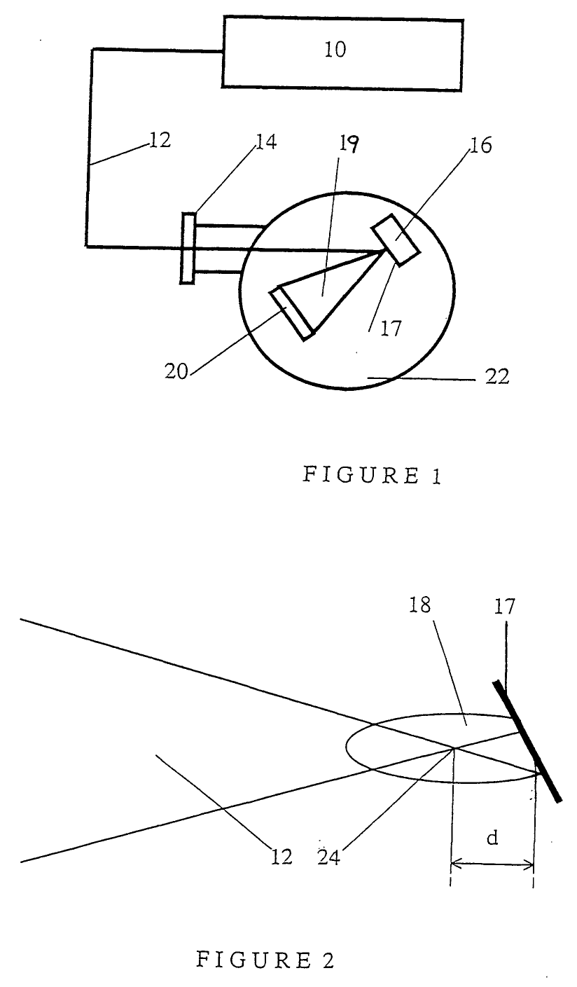

Referring to FIG. 1, a laser 10 generates a pulsed beam 12 which is guided by optics (not shown) and focussed by lens 14 at a small but finite distance in front of a target 16. In this embodiment of the invention, the laser 10 is a 10 kHz, 20 ns, Copper-Vapour Laser (CVL), the pulse energy is 2 mJ per pulse, and the wavelength of the laser beam is 510 nm. Target 16 and substrate 20 are contained within chamber 22, preferably a vacuum chamber. The vacuum is preferably of the order of 10⁻³ Torr or better. For the production of diamond or diamond-like films, the target 16 is made of graphite.

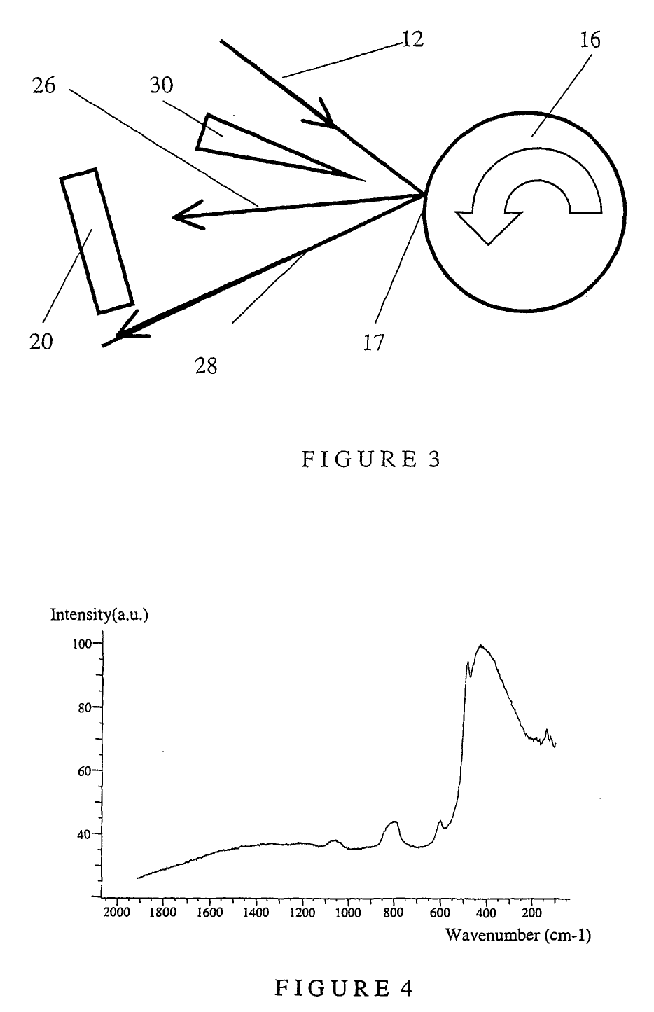

Advantageously, the target 16 is cylindrical (FIG. 3) and rotates about its longitudinal axis, which extends normal to the axis of incident laser beam 12. Rotation of the target 16 avoids successive laser pulses striking the same spot on the target surface 17 (eliminating crater formation). The laser beam 12 or target 16 may additionally or alternatively be scanned in the plane perpendicular to the axis of the laser beam to avoid crater formation.

The incident beam may be directed onto the target 16 at an angle to the target surface 17. In a preferred embodiment, the target 16 is 40 mm in diameter and rotates about its axis at 10⁴ rev/min. It will be appreciated that target 16 may be of any of a number suitable shapes (suitable shapes including, for example, generally rectangular, spherical, or cylindrical shapes) and may be moved or scanned in any conventional manner of the kind that would be appreciated by those of ordinary skill in the art.

Interaction of the laser beam 12 with the surface 17 of the target 16 gives rise to a laser plume 18 (FIG. 2) of ablated material which propagates towards and is deposited on a substrate 20. Region 19 shown in FIG. 1 shows the direction of propagation of plume 18 towards substrate 20. The substrate 20 is conveniently positioned 95 mm away from the target 16. A basis for selecting this distance will be discussed below. Typical target to substrate distances are in the range of a few centimetres to 20 cm. The substrate 20 may optionally be heated to assist in the adhesion of the deposited layers of film to the substrate. In some embodiments of the invention however, heating is not required.

This invention is partly based on the observation that in order to produce a high quality thin film, in particular a diamond thin film, a good quality plume is required. After absorption by the solid surface of a target a plasma-plume is formed which consists of a mixture of energetic species such as atoms, molecules, electrons, ions, clusters, and micron-sized solid particulates. The presence of significant amounts of micron-sized particulates is usually a disadvantage for the best outcome of this process. A good quality plume is therefore one which contains relatively few micron-sized particulates and in which the atoms and ions possess an energy level appropriate to the film being formed. For example, it has been suggested that in order to obtain the sp³ carbon-carbon bonds of a diamond structure, the ablated atoms and ions should possess an energy of the order of 100 eV to 200 eV and preferably in the range 70-200 eV.

In order to achieve evaporation and ablation of the target material, the flux energy of the laser pulses is preferably above a predetermined threshold. It has been demonstrated that the threshold flux energy for graphite evaporation is 30 MW/cm² (Danilov et al, Sov. J. Quantum Electron. 18 (12) December 1988 at page 1610). In the case where the target material is graphite, a pulse energy flux that is too low results in the creation of graphite structures or other non-diamond carbon films, while a pulse energy flux that is too high results in contaminating particles of materials being ejected from the surface of the target and deposited on the substrate, or in the substrate being damaged by high energy impinging particles. In embodiments of this invention where the target material is graphite, the pulse energy flux on the target surface is preferably in the range of 5×10⁸-10⁹W/cm².

FIG. 2 illustrates the production of a good quality plume using a pulsed laser 10, with low pulse energy and nanosecond pulse duration. The laser flux at the target surface 17 was obtained using lens 14 and focussing the laser beam 12 at a finite distance d in front of the target surface 17. The distance d is preferably in the range of 1 μm to 10 mm, most preferably about 0.46 mm, in front of the target surface. The distance d is dependent on the laser flux and other parameters.

Placing the focal point of the lens 14 in front of the target surface 17 advantageously places the focal region 24 of the beam within the laser plume 18. The focal region 24 of the beam 12 is defined as the region of the laser beam 12 immediately before and after the optical focal point of the lens 14, where the cross-section of the beam is approximately equal to the diameter of the beam at the optical focal point. The cross-section of the beam 12 is typically generally circular or elliptical. As a result, the laser beam is of greater than minimum cross-section, and therefore less than maximum energy concentration, at the target surface. Target material is evaporated and ablated by the laser pulses, however the energy of the ablated evaporants within the plume itself is not sufficiently high to enable the formation of a diamond film.

Positioning the focal region 24 of the beam 14 in front of the target surface 17 provides additional energy to the evaporants so that a diamond film can be formed. In this case, the focal region 24 increases the plasma temperature of the laser plume 18 and the evaporants within the plume become more energetic, as discussed further below. That is, the evaporants within the laser plume 18 have an initial energy provided by the laser pulses striking the target surface 17. This energy is then increased by the interaction of the laser plume 18 with the focal region 24 of the lens 14.

Within the plume of ablated material there is a region in which the density of the evaporants is a “critical density”. In this specification the expression “critical density” is defined as the density of evaporants that is sufficient to permit effective absorption of the laser energy within the plume. The critical density, n, depends on the laser wavelength, λ (μm), and can be quantified by reference to the formula n=1.1×10²¹/λ². In one preferred embodiment, the critical density of evaporants is 4×10²¹ evaporants/cm³. The energy absorption by the evaporants only becomes significant when the laser flux is near 10¹⁰ W/cm², or more.

The input of laser energy in the region of critical density will produce a “shock wave” effect or plasma wave, that expands in the solid angle of 4π, and is centralised at the optical focal point of lens 14. Evaporants at the centre of the shock wave, i.e. at the focus of the laser and in the region of critical density, absorb the energy of the laser and become more energetic. Faster, energetic evaporants that have passed beyond the focal point are accelerated by the front end of the shock wave, away from the target surface. Slower, less energetic particles that have not reached the focal point have their energy increased but are affected by the back end of the shock wave and are pushed back towards the target surface.

The flux of the laser beam at the critical point is preferably from 10¹⁰ watt/cm² and may be up to 10¹⁴ watt/cm². In a particularly preferred embodiment of the invention, the flux of the laster beam is of the order of 10¹¹ Watt/cm².

By focussing the laser beam in the critical density region of the plume, a shock wave is produced which effectively acts as a velocity filter. Particles that have an energy sufficient to have reached or passed the region of critical density have their energy increased and are accelerated towards the substrate, while low energy, slower evaporants are pushed back towards the target surface. For the production of diamond film, the velocity of the evaporants striking the substrate is preferably between 3×10⁶ cm/s to 9×10⁶ cm/s. A particularly preferred velocity is 5×10⁶ cm/s.

In one example of the operation of this embodiment, the laser flux at the target surface 17 was 1.5×10⁹W/cm² and the radius of the spot on the target surface 17 was 4.6×10⁻³ cm. The focussing lens 14 had a focal length of 15 cm and the mid-point of the focal region was 0.46 mm from the target surface. The density of the evaporants in the region of critical density was 4×10²¹ evaporants/cm³ and the laser flux was near 10¹¹W/cm².

The length (L) of the focal region can be calculated as follows:

L=0.414f².θ/D

where: f is the focal length of the lens;

θ is the divergence of the beam; and

D is the diameter of the beam in the lens.

The use of a short focal length lens, preferably less than 35 cm, enables the optimal laser beam flux for the evaporation of graphite to be obtained and, when compared to longer focal length lenses, provides a much more powerful density in the focal region 24 of the lens 14 to boost the effectiveness of the energetic input into the laser plume 18.

The deposition of evaporants on the substrate 20 is illustrated in FIG. 3. As described above, laser beam 12 is focussed a short distance in front of the target surface 17. The target 16 is a graphite cylinder rotated on its longitudinal axis.

The interaction of the laser beam 12 with the target surface 17 results in the formation of a plume 18 of evaporants which propagates towards substrate 20. Without the influence of any shields or external forces, a range of evaporants is deposited on the substrate 20, although optionally, shields and external forces can be employed in other embodiments of the invention. It has been noted that the slower moving i.e. low energy evaporants are the heavier, larger particulates that are not desired in the production of high quality thin films, while the single atoms and ions are relatively fast moving.

In addition to the velocity filtering method described above, a further method of restricting the type of evaporants being deposited on the substrate 20, is to rotate the target 16 especially at high speed on its (or a) longitudinal axis of the target. This rotation not only avoids successive laser pulses striking the same spot on the target surface 17 (eliminating crater formation), but imparts a significant component of velocity to the evaporants. The component of velocity of the ablated particles is preferably substantially tangential to the target surface 17. In one embodiment of the invention, the rotational speed of the target is 10⁴ rev/min. This speed of rotation results in particles having a velocity of less than 10⁴ cm/s being deflected away from the substrate. The rotational speed of the target is preferably greater than 2000 rev/min, more preferably greater than 5000 rev/min, and may be up to 40,000 rev/min.

It will be appreciated that the speed of rotation of the target 16 can be adjusted to correspond to the distance of the substrate from the target surface. For example, if the substrate is closer to the target then the rotational speed should be increased.

As illustrated in FIG. 3, the component of velocity has a greater effect on slow moving particles than on fast moving atoms and ions. The direction of propagation of fast evaporants is indicated by the trace 26, i.e. the direction of these evaporants is substantially unaffected by the tangential component of velocity. The trace 28 of the slower evaporants clearly shows the effect of the tangential component of velocity. These slower moving particles are deflected from their propagation direction and are directed away from the substrate 20. A shield 30 may optionally be placed to one side of the substrate 20 to assist in preventing unwanted evaporants being deflected onto the substrate 20.

Persons of ordinary skill in the art-will appreciate that because the number of evaporants propagating in the direction of the substrate is reduced, the rate of evaporants being deposited on the substrate is also reduced. A preferred rate of deposition is in the range of 0.5 to 25 Å/min, more preferably 2 to 10 Å/min and in one embodiment, the rate of deposition is 5 Å/min. This slow rate of deposition relative to conventional rates (e.g. 0.8 to 6 Å/s) is believed to further assist in the formation of even, smooth layers of material on the substrate. The rate of deposition may be increased by increasing the pulse repetition rate.

Using the method of the preferred embodiment, a substantially pure diamond (i.e. sp³ bonded carbon) thin film on a silicon substrate has been readily obtained. The film appeared to be substantially free or almost free of both sp² bonded particles and contaminant particulates.

Thin films produced by the applicant have been examined by Raman microspectroscopy to confirm the chemical nature of deposited films as a form of synthetic diamond. The Raman spectrum of one of these films is shown in FIG. 4.

Because the Raman intensity of graphite is more than 50 times larger than the Raman intensity measured for diamond (using a 785 nm wavelength), the Raman spectrum is a very effective means of detecting the presence of graphite on thin films. For the spectrum reported here the substrates were quartz and Si(100) wafers.

The sp³ vibrational modes found to extend over a broad range centred near 1100 cm⁻¹, while the sp² sites exhibited vibrational frequencies above 1600 cm⁻¹. For the spectrum in FIG. 4 no graphitisation of carbon was indicated. The characteristic strong Raman peak centred at 1333 cm⁻¹ of single gem diamond crystal was not observed, one reason for this being that the diamonds on the film that were to be observed were nanometer-sized. A second reason why the previously mentioned characteristic peak was not observed was that the thickness of the film was at least five times less than that of the microprobe.

Atomic force microscopy (AFM) was also used to observe the surface morphology of the same sample. It was observed that the silicon substrate was covered by a small-grained, poly-crystalline continuous film. The highest crystalline feature found on the surface of sample was 70 nm in height. An average surface roughness of 15 nm was obtained for the films with 200 nm thickness. AFM was also used to examine the electrical conductivity of the film. According to the AFM images of the electrical current, the film was found to be completely non-conductive.

It will be appreciated by those of ordinary skill in the art that the described method is not confined to the production of diamond thin films but also has applications in the production of other high quality thin films by laser ablation and deposition techniques. For example, while, in the embodiment described above, the method aspect of the invention has been described as being conducted in a vacuum, the method of the invention may also be conducted in a nitrogen atmosphere for the production of nitride films or in the presence of a variety of one or a combination of two or more ambient or introduced gases. It will also be appreciated that other substrate materials may be used, including plastics, glass, quartz, and steel, for example.

While the embodiment of the invention described above utilised a cylindrical, homogenous graphite target that was rotated on its longitudinal axis, other shapes and materials of targets may be employed by the method of the invention in order to produce a thin film having the desired composition. For example, the target may be a rectangular slab made entirely of one material or a composite of materials. A composite target may have layers of graphite, copper, and nickel for example, or in the case of a cylindrical target, the target may be segmented into the different materials.

Where the target is made up of multiple materials, the laser beam may be scanned across the respective surfaces of each material producing a plume of evaporants from each material in the process. Equally, the laser beam may be held stationary while the target is scanned.

Those skilled in the art will also appreciate that while the above description of the invention has been directed to the use of a single laser, the method of invention could also be performed using two or more lasers or one laser split into multiple beam components. Where two laser beams are used, one laser beam could be used to ablate material from the target surface while the second laser beam could be focussed within the plume and used to energise the evaporants within the plume as described above.

Multiple laser beams could also be employed when a polycomponent target is used, with each of the laser beams being directed onto respective material surfaces. In the embodiments where multiple laser beams are used on a polycomponent target, the laser flux of each beam may be selected to suit the respective components of the target.

It will be understood that the invention disclosed and defined in this specification extends to all alternative combinations of two or more of the individual features mentioned or evident from the text or drawings. All of these different combinations constitute various alternative aspects of the invention. evaporants from said target surface within said plume, and thereby producing a shockwave of evaporants within said plume.

22. A method according to 21, wherein said laser ablation of said target surface is effected by said focused laser beam.

23. A method according to claim 21, wherein evaporants within said plume that have propagated beyond said region of critical density in a predetermined time are accelerated by said shockwave towards said substrate while evaporants within the plume that have not propagated beyond said region of critical density in said predetermined time are accelerated by the shockwave towards said target surface.

24. A method according to claim 21, wherein the minimum cross-section of the laser beam comprises a focal region of the laser beam.

25. A method according to claim 21, wherein said laser ablating is carried out by a first laser beam and a second laser beam is used for focusing.

26. A method according to claim 21, further comprising imparting a predetermined component of velocity to the evaporants such that slower moving evaporants within the plume are caused, by the component of velocity, to deflect from said propagation direction and are prevented from being deposited on said substrate.

27. A method according to claim 26, wherein said predetermined component of velocity is imparted by movement of said target surface.

28. A method according to claim 27, wherein said target surface is cylindrical and said movement of said target surface comprises high speed rotation of said cylindrical target surface.

29. A method according to claim 28, wherein said predetermined component of velocity is substantially tangential to said target surface.

30. A method of depositing a thin film on a substrate, the method comprising:
laser ablating a target surface to create a plume of evaporants, having a range of velocities within said plume, extending in a propagation direction away from said target surface;
focusing a laser beam at a selected distance before said target surface so as to position a minimum cross-section of said laser beam resulting from said focusing within said plume, thereby imparting increased energy to the evaporants within said plume;
positioning the substrate in the propagation direction of said plume;
imparting a predetermined component of velocity to the evaporants; and
wherein said substrate is positioned at a predetermined distance from said target surface such that the slower moving evaporants within said plume are caused by the component of velocity to deflect from said propagation direction, and are prevented from being deposited on said substrate.

31. A method according to claim 30, wherein said laser ablation of said target surface is effected by said laser beam.

32. A method according to claim 30, wherein said plume includes a region of critical density and said laser beam is focused within said region of critical density.

33. A method according to claim 32, wherein a shockwave is produced in said plume.

34. A method according to claim 33, wherein evaporants within said plume that have propagated beyond said region of critical density in a predetermined time are accelerated by said shockwave towards said substrate while evaporants within the plume that have not propagated beyond said region of critical density in said predetermined time are accelerated by said shockwave towards said target surface.

35. A method according to claim 30, wherein said laser beam is a second laser beam and said laser ablation is effected by a first laser beam.

36. A method according to claim 30, wherein said component of velocity is imparted by movement of said target surface.

37. A method according to claim 36, wherein said target surface is cylindrical and said movement of said target surface comprises high speed rotation of said cylindrical target surface.

38. A method according to claim 37, wherein the component of velocity is substantially tangential to said target surface.

39. A method of depositing a thin film on a substrate, the method comprising:
laser ablating a target surface to create a plume of evaporants, having a range of velocities within said plume, extending in a propagation direction away from said target surface;
positioning the substrate in said propagation direction of said plume;
imparting a predetermined component of velocity to the evaporants as the evaporants are ablated from said target surface; and
wherein said substrate is positioned at a predetermined distance from said target surface such that slower moving evaporants within the plume are caused, by said predetermined component of velocity, to deflect from said propagation direction and are prevented from being deposited on said substrate.

40. A method of forming thin films on a substrate by laser ablation of a target to form a deposition plume of evaporants including a region of critical density wherein a laser beam flux in said region of critical density in said plume is adjusted to obtain effective energy absorption by the evaporants said that said evaporants attain sufficient energy to deposit on said substrate; said substrate being positioned said that evaporants having energy levels outside a predetermined range are not deposited on said substrate.

41. A method according to claim 40, wherein said laser beam is focused in said region of critical density in said plume.

42. A method according to claim 40, wherein a shockwave is produced in said plume.

43. A substrate having a thin film deposited thereon according to the method of any of claims 31, 30, 39 and 40.

44. A substrate according to claim 43 wherein said thin film is a diamond film.
